(19) United States
(12) Patent Application Publication
(10) Pub. No.: US 2026/0024590 A1
(43) Pub. Date: Jan. 22, 2026

(54) CROSS TEMPERATURE READ VOLTAGE CALIBRATION FOR A MEMORY SYSTEM

(71) Applicant: Micron Technology, Inc., Boise, ID (US)

(72) Inventors: Li-Te Chang, San Jose, CA (US); Murong Lang, San Jose, CA (US); Chao-Han Cheng, San Jose, CA (US)

(21) Appl. No.: 19/243,558

(22) Filed: Jun. 19, 2025

Related U.S. Application Data
(60) Provisional application No. 63/672,607, filed on Jul. 17, 2024.

(51) Int. Cl. G11C 16/26; G06F 3/06; G11C 16/10

(52) U.S. Cl. CPC G11C 16/26; G06F 3/061; G06F 3/0659; G06F 3/0679; G11C 16/10

(57) ABSTRACT

Methods, systems, and devices for cross temperature read voltage calibration for a memory system are described. A memory system may generate read voltage offsets to apply to memory cells during a refresh or calibration operation based on a combination of both a read voltage shift associated with charge loss and cross-temperature conditions of the memory cells. The memory system may program memory cells at a first time and determine a first shift in read voltage for a first logic state as well as a first change in temperature between the first time and second time at which the memory cells are read out. The final read trims to apply during refresh may be calculated by inputting the read voltage shift and the change in temperature to a machine learning (ML) model, a combination of look-up tables (LUTs), or both, each of which may be trained to output read trim values.

### CROSS REFERENCE

The present application for patent claims priority to U.S. Patent Application No. 63/672,607 by Chang et al., entitled “CROSS TEMPERATURE READ VOLTAGE CALIBRATION FOR A MEMORY SYSTEM,” filed Jul. 17, 2024, which is assigned to the assignee hereof, and which is expressly incorporated by reference in its entirety herein.

### TECHNICAL FIELD

The following relates to one or more systems for memory, including cross temperature read voltage calibration for a memory system.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports cross temperature read voltage calibration for a memory system in accordance with examples as disclosed herein.

FIG. 2 shows an example of a graph that supports cross temperature read voltage calibration for a memory system in accordance with examples as disclosed herein.

FIGS. 3A and 3B show examples of read voltage calibration schemes that support cross temperature read voltage calibration for a memory system in accordance with examples as disclosed herein.

FIGS. 4A and 4B show examples of flowcharts that support cross temperature read voltage calibration for a memory system in accordance with examples as disclosed herein.

FIG. 5 shows a block diagram of a memory system that supports cross temperature read voltage calibration for a memory system in accordance with examples as disclosed herein.

FIG. 6 shows a flowchart illustrating a method or methods that support cross temperature read voltage calibration for a memory system in accordance with examples as disclosed herein.

### DETAILED DESCRIPTION

In some memory systems (e.g., in automotive applications), memory cells in a memory system may experience instability due to cross-temperature conditions. A cross-temperature condition of a memory cell may be based on a change in temperature between a set up temperature (TSU) at a first time that the memory cell is programmed and a read out temperature (TRO) at a second time that time memory cell is read from or refreshed. The temperature changes may cause relatively large shifts in read voltage levels that are used to read and access various logic states stored by the memory cells. A memory system may perform a read voltage calibration process (e.g., block family error avoidance (BFEA)) to refresh memory cells and to ensure that the read voltage levels for various logic states stored in memory cells of the memory system are accurate and do not shift significantly over time. In some cases, however, the read voltage calibration process may fail to account for read voltage shifts which occur as a result of cross-temperature conditions at the memory system. In systems associated with relatively large temperature changes over time (e.g., automotive systems), the read voltage calibration that is performed without consideration to the effects of cross-temperature may be less accurate, resulting in a relatively high frequency of refreshes and relatively inaccurate read voltages applied to memory cells during host access operations, which may result in read errors, memory access delays, and increased write amplification.

In accordance with examples described herein, a read voltage calibration process by a memory system may generate read voltage offsets to apply to memory cells of the memory system based on read voltage shifts due to both slow charge loss (SCL) (e.g., discharge of voltage from the cell over time) as well as read voltage shifts due to cross-temperature conditions of memory cells within the memory system. The read voltage offsets to apply to the memory during refresh may be based on a combination of SCL read offsets associated with compensating for charge loss over time and read offsets as associated with compensating for cross-temperature changes. The read trims to apply to the memory cells during refresh may be calculated using a linear regression model, an artificial intelligence (AI) or machine learning (ML) model, a combination of one or more look-up tables (LUTs), or any combination thereof, each of which may be trained prior to deployment of the memory system based on both cross-temperature data or conditions and charge loss over time. Accounting for both first read voltage shifts due to SCL and second read voltage shifts due to cross temperature may improve accuracy of refresh operations, may reduce a frequency of performing refresh, and may decrease write amplification, which may improve system performance and reduce processing at the memory system, among other examples.

In addition to applicability in memory systems as described herein, techniques for cross temperature read voltage calibration for a memory system may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by increasing accuracy of refresh operations and reducing a frequency of refresh, which may decrease processing or latency times, improve system performance, improve response times, or otherwise improve user experience, among other benefits.

Features of the disclosure are illustrated and described in the context of systems, devices, and circuits. Features of the disclosure are further illustrated and described in the context of graphs, read voltage calibration schemes, flow diagrams, block diagrams, and flowcharts.

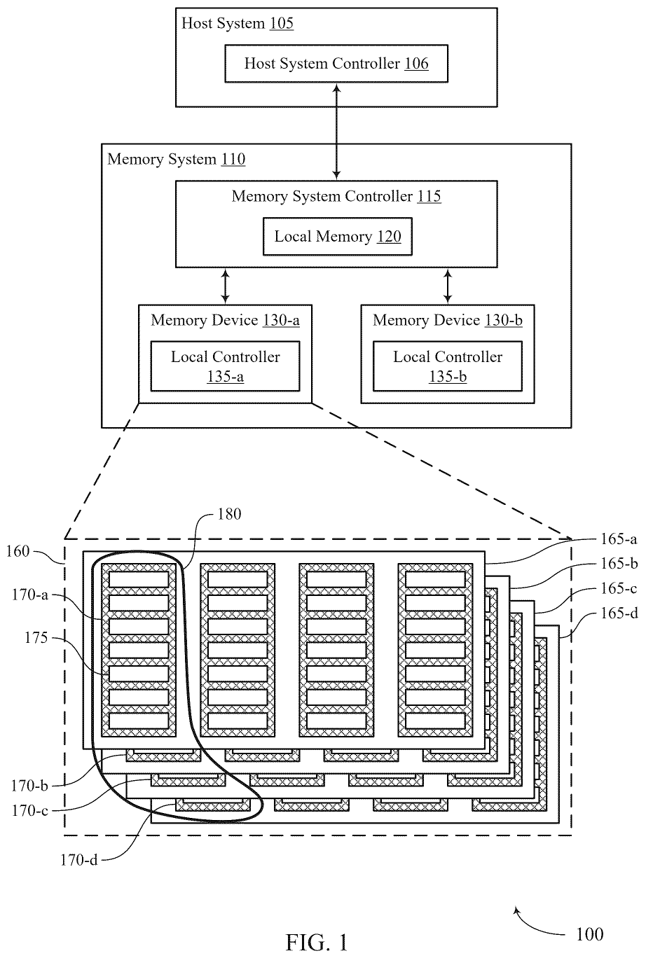

FIG. 1 shows an example of a system 100 that supports cross temperature read voltage calibration for a memory system in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

Each memory cell of the NAND memory device 130 may be programmed to store a logic value representing one or more bits of information. In some cases, a single memory cell—such as an SLC memory cell—may be programmed to one of two supported states and thus may store one bit of information at a time (e.g., a logic 0 or a logic 1). In other cases, a single memory cell—such as an MLC, TLC, QLC, or other type of multiple-level memory cell—may be programmed to one or more than two supported states and thus may store more than one bit of information at a time. In some examples, a single MLC memory cell may be programmed to one of four supported states and thus may store two bits of information at a time corresponding to one of four logic values (e.g., a logic 00, a logic 01, a logic 10, or a logic 11). In some examples, a single TLC memory cell may be programmed to one of eight supported states and thus may store three bits of information at a time corresponding to one of eight logic values (e.g., 000, 001, 010, 011, 100, 101, 110, or 111). In some examples, a single QLC memory cell may be programmed to one of sixteen supported states and thus may store four bits of information at a time corresponding to one of sixteen logic values (e.g., 0000, 0001, . . . 1111).

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some memory systems 110 (e.g., in automotive applications), memory cells in a memory system 110 may experience instability due to cross-temperature conditions. A cross-temperature condition of a memory cell may be based on a change in temperature between a set up temperature (TSU) at a first time that the memory cell is programmed and a read out temperature (TRO) at a second time that time memory cell is read from or refreshed. The temperature changes may cause relatively large shifts in read voltages for the memory cells. Read voltage calibration may be performed to refresh memory cells and to ensure that the read voltage levels for various logic states stored in memory cells of the memory system are accurate and do not shift more than a threshold amount over time. However, cross-temperature conditions may not be accounted for in read voltage calibration operations. In memory systems 110 associated with relatively large temperature changes over time, the read voltage calibration that is performed without consideration to the effects of cross-temperature may be less accurate, resulting in a relatively high frequency of refreshes and relatively inaccurate read voltages when performing host access operations (e.g., to a host system 105), which may result in read errors and memory access delays.

In accordance with examples described herein, a read voltage calibration process may generate read voltage offsets to apply to memory cells of the memory system 110 to refresh the memory cells based on both a read voltage shift due to SCL as well as cross-temperature conditions of memory cells within the memory system. The read voltage offsets to apply to the memory during refresh may be based on a combination of SCL read offsets across time and read offsets determined as a function of cross-temperature. The final read trims may be calculated using a linear regression model, an artificial intelligence (AI) or machine learning (ML) model, or a combination of one or more look-up tables (LUTs), each of which may be trained before deployment of the memory system based on cross-temperature data or conditions. Accounting for both first read voltage shifts due to SCL and second read voltage shifts due to cross temperature may improve accuracy of refresh operations and may reduce a frequency of performing refresh, which may improve system performance and reduce processing at the memory system.

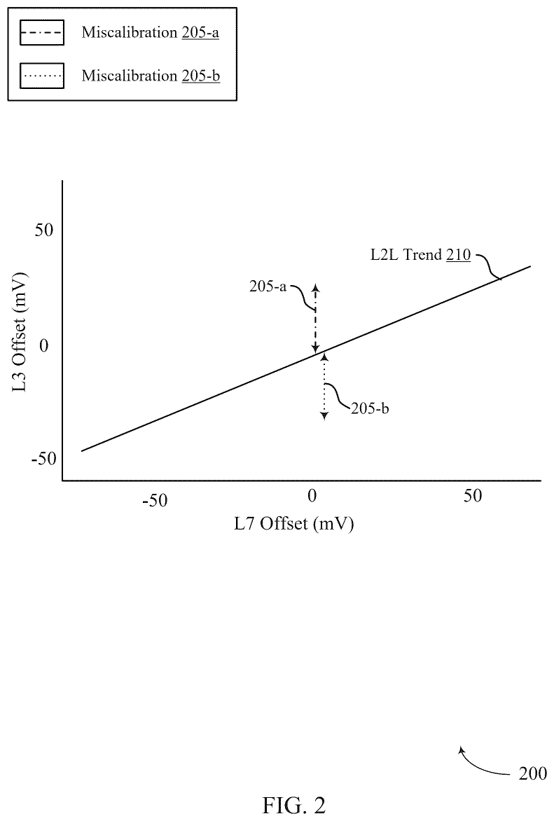

FIG. 2 shows an example of a graph 200 that supports cross temperature read voltage calibration for a memory system in accordance with examples as disclosed herein. The graph 200 may implement or may be implemented by aspects of the system 100. For example, the graph 200 may illustrate read voltage shifts (e.g., in millivolts (mV) or some other unit) corresponding to various logic states stored in memory cells of one or more memory devices 130 of a memory system 110. In some examples, a memory system 110 may estimate read voltage shifts for performing refresh of memory cells in accordance with the graph 200 (e.g., by identifying a level-to-level (L2L) trend 210 between two logic states).

As part of a read voltage calibration process (e.g., BFEA or some other calibration or refresh operation), a memory system may measure voltage shifts (e.g., due to SCL) of a first logic state over time (e.g., based on a time since a corresponding memory cell storing the first logic state was programmed) and may identify correlations (e.g., trends, relationships) between the voltage shifts of the first logic state and respective voltage shifts of other logic states over time that may be stored in memory cells of the memory system. The first logic state may be a highest logic state (e.g., ‘111’) of a set of multiple logic states that are stored in memory cells of the memory system. For example, the memory cells may be tri-level cells (TLC) and may each store one of eight logic states. Additionally, or alternatively, the memory cells may be single-level cells (SLC) and may each store one of two logic states, may be multi-level cells (MLC) and may each store one of four logic states, or may be quad-level cells (QCL) and may each store one of 16 logic states, or any combination thereof.

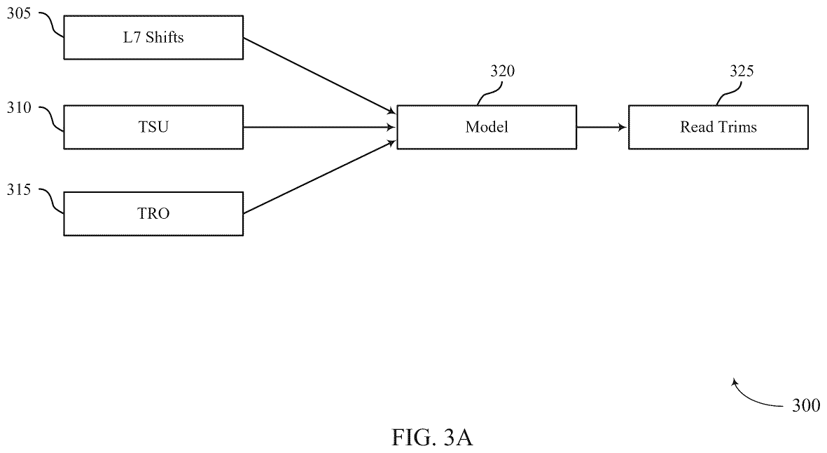

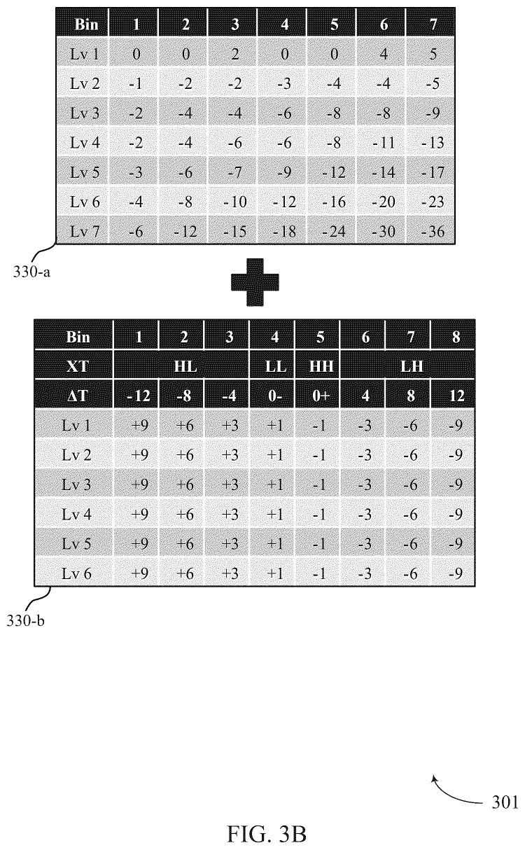

The multiple logic states which may be stored in the memory cells may be referred to herein with respect to corresponding levels, which may refer to a voltage level (e.g., a voltage range, a read voltage threshold) that is applied to the memory cell to read the corresponding logic state. The voltage shifts measured for the first logic state over time may be referred to herein as first level shifts (e.g., level 7 shifts, level 7 offsets in the example of TLC), which may refer to shifts in read voltage associated with accessing (e.g., reading) the first logic state. The first level (e.g., level 7 for TLC) may be a greatest read voltage threshold of the multiple read voltage thresholds (e.g., levels 1-7 for TLC) associated with the multiple logic states. Measuring read voltage shifts for level 7 (e.g., level 7 shifts) is used as an illustrative example in the graph 200, but it is to be understood that the first level shifts measured by the memory system may refer to other levels (e.g., level 1 for SCL, level 3 for MCL, level 15 for QCL, or the like). The memory system may use the first level shifts as a reference (e.g., in accordance with a LUT, as described in greater detail with reference to FIG. 3B) for determining read voltage shifts to apply to the other levels (e.g., other logic states) associated with the memory cells, which may reduce processing power and save time as opposed to measuring the read voltage shifts for each level. The highest logic state may be tracked because the highest logic state may be associated with a highest stored charge, among other examples.

The memory system may determine a L2L trend 210 between read voltage shifts of a first level (e.g., level 7) and respective read voltage shifts of each other level of the multiple levels associated with memory cells of the memory system. In the example of graph 200, the memory system may determine the L2L trend 210 between read voltage shifts of the first level and read voltage shifts of a second level (e.g., level 3). The L2L trend 210 may be based on SCL (e.g., one or more SCL measurements during previous operations, testing operations, or any combination thereof). The L2L trend 210 may be a trend line that represents an average relationship between read offset voltages for different logic states. It is to be understood that the correlation of read voltages across levels may generally be linear, but some read offset voltages may vary or stray from the trend line. Thus, the trend 210 illustrates an averaged relationship between logic states. The slop for this relationship may vary for different logic states, but a general linear trend line may be identified between the first level (e.g., level 7) and each other logic level of the memory cells.

However, other factors, such as cross temperature conditions at memory cells of the second level, may also impact the read voltage shift at memory cells. The cross temperature impact may not correspond to a linear correlation between changes across logic levels, in some examples, and may result in a miscalibration 205 of the read voltage shift for memory cells of the second level based solely on the trend 210. In some examples, memory cells may be programmed at a first temperature (e.g., TSU) and may be read or refreshed at a second temperature (e.g., TRO) less than the first temperature (e.g., a high-low (HL) cross-temperature condition). The voltage stored by the memory cell may increase due to the temperature change. As such, if using the original read voltages for the first level based on the temperature at the program time, the memory system may not correctly calibrate to other voltage levels for other logic states. For example, as illustrated in FIG. 2, a HL cross-temperature condition may result in a miscalibration 205-a (e.g., +30 mV difference in read voltage shift for a given logic state, or some other difference). Additionally, or alternatively, memory cells may be programmed at a first temperature and may be read or refreshed at a second temperature greater than the first temperature (e.g., a low-high (LH) cross-temperature condition). The voltage stored by the memory cell may decrease due to the temperature change. As such, if using the original read voltages for the first level based on the temperature at the program time, the memory system may not correctly calibrate to other voltage levels for other logic states. For example, as illustrated in FIG. 2, a LH cross-temperature condition may result in a miscalibration 205-b (e.g., −30 mV difference in read voltage shift for a given logic state, or some other difference).

In accordance with examples described herein, the memory system may determine the first level shifts (e.g., a shift or change in a read voltage for a first logic state between a program time and a readout time), a TSU, and a TRO of a memory cell (e.g., to be refreshed), and the memory system may determine read voltage offset values for read voltage calibration of the memory cell based on the first level shifts, the TSU, and the TRO. By utilizing the TSU and TRO measurements (e.g., and in accordance with cross-temperature trends of memory cells, which may be predetermined and loaded into one or more models or LUTs stored at the memory system) to determine the read voltage offset values to apply to memory cells, the memory system may support greater accuracy in read voltage calibration and may reduce errors caused by the miscalibrations 205, among other examples, in systems where temperatures may vary over time (e.g., automotive systems, or other temperature-variable systems).

FIG. 3A shows an example of a read voltage calibration scheme 300 that supports cross temperature read voltage calibration for a memory system in accordance with examples as disclosed herein. The read voltage calibration scheme 300 may implement or may be implemented by aspects of the system 100. For example, the read voltage calibration scheme 300 may include model 320 (e.g., a linear regression model, an AI/ML model), which may be implemented by a memory system 110 (e.g., a memory system controller 115, one or more local controllers 135, or a combination thereof).

The model 320 may be configured to estimate a relationship between read voltage shifts of a first logic state of a memory cell (e.g., first level shifts, level 7 shifts), a time since a write (e.g., a time since programming a memory cell, a program time), and a change in temperature (e.g., a difference between TSU and TRO) across multiple logic states supported by memory cells of the memory system. For example, the model 320 may receive, as inputs, a set of first level shifts 305, a TSU 310, and a TRO 315. Based on the inputs, the model 320 may output read trims 325, which may be applied to memory cells of a memory system as part of a read voltage calibration process.

In some examples, the model 320 may be a linear regression model. The linear regression model may include multiple L2L linear regressions (e.g., which may each be based on a respective L2L trend 210, as described with reference to FIG. 2, but may account for various other factors, such as temperature) which may be generated, for each word line group, based on potential values (e.g., or groupings of similar values) of the set of first level shifts 305, the TSU 310, and the TRO 315. In some examples, the L2L linear regressions may be similar to the L2L trends 210, as described with reference to FIG. 2, but may be modified to account for different cross-temperature conditions. For example, the multiple L2L linear regressions included in the linear regression model may include a respective L2L linear regression for each cross-temperature condition (e.g., HL, LH, low-low (LL), high-high (HH)) or for each range of multiple ranges of cross-temperature difference (e.g., difference between TSU and TRO). Additionally, or alternatively, the model 320 may be an AI model. The AI model may be a neural network model or a deep learning model.

The model 320 may be trained during one or more manufacturing processes associated with the memory system. For example, the model 320 may be trained prior to deployment of the memory system. Additionally, or alternatively, the model 320 may be trained in accordance with one or more testing processes or procedures. For example, the model 320 may be trained using testing data, which may cover the potential use cases of the memory system (e.g., including corner cases) based on factors such as cross-temperature conditions and slow charge loss. The trained model 320 may be loaded to the memory system, or the model may be loaded and subsequently trained, and the memory system may utilize the model 320 during operation to determine read voltage offset values to apply during read voltage calibration operations. By utilizing the model 320, the memory system may support more accurate calibration of read voltages associated with memory cells, which may result in fewer refreshes performed and increased system performance.

The model 320 may output read trims 325, which may indicate read voltage offset values to be applied to memory cells of the memory system during read voltage calibration. The read trims 325 may include read trims associated with multiple logic states and multiple word line groups of memory cells of the memory system. That is, the read trims 325 may include a read trim corresponding to each logic state of the multiple logic states and within each word line group of the multiple word line groups.

FIG. 3B shows an example of a read voltage calibration scheme 301 that supports cross temperature read voltage calibration for a memory system in accordance with examples as disclosed herein. The read voltage calibration scheme 301 may depict a mapping 330-a (e.g., a base LUT) and a mapping 330-b (e.g., an add-on LUT) that are stored to or accessible by a controller (e.g., a memory system controller 115 as described with reference to FIG. 1) and are used in combination by the controller to make an adjustment of one or more reference voltage values for a memory device.

In some examples, the mapping may include reference voltage value adjustments for each level of multiple different levels (e.g., Lv1 through Lv7) and each bin of multiple candidate bins. A bin may correspond to a range of time for storing data in a memory cell, a range of cross-temperature differences (e.g., a temperature delta), or both. That is, a bin may generally correspond to a respective range of values for a given parameter that may affect read voltages (e.g., time or temperature). While the mapping 330-a and the mapping 330-b provide specific reference voltage adjustment values for different levels and bins, it is to be understood that the values depicted in FIG. 3B are for exemplary purposes only. Thus, the mapping 330-a and the mapping 330-b may provide a controller or other component of a memory device any set of reference voltage value adjustments, and the specific values stored to the mapping may be a matter of design. Regardless of the specific values stored to the mapping 330-a and the mapping 330-b, adjusting the reference voltage values for a memory device based on the cross-temperature conditions related to one or more memory cells in addition to a duration that data has been stored to the one or more memory cells may improve the memory device's ability to accurately sense sets of memory cells that may be affected by cross-temperature instability or degradation.

The mapping 330-a and the mapping 330-b may include reference voltage value adjustments for respective levels and bins associated with a word line group of a memory device (e.g., the mapping 330-a and the mapping 330-b may be associated with word line group-based adjustments to reference voltages for all memory cells within that word line group). There may be separate mappings for each word line group within a memory device, in some examples. As described herein, the levels may represent a midpoint voltage value between two states of the memory cell. For example, level 1 may be positioned between logic state ‘000’ and ‘001’, level 2 may be positioned between logic state ‘001’ and ‘010’, level 3 may be positioned between logic state ‘010’ and ‘011’, level 4 may be positioned between logic state ‘011’ and ‘100’, level 5 may be positioned between logic state ‘100’ and ‘101’, level 6 may be positioned between logic state ‘101’ and ‘110’, and level 7 may be positioned between logic state ‘110’ and ‘111’.

Thus, although FIG. 3B illustrates seven (7) levels, the mapping 330-a or the mapping 330-b may include different quantities of levels. For example, seven (7) level may represent a TLC (e.g., a memory cell configured to store one of eight (8) logic states, thus being associated with seven levels), whereas three (3) levels may represent a MLC, and one (1) level may represent a single-level cell (SLC). Other configurations for other types of memory cells (e.g., SLC, MLC, TLC, QLC, etc.) may also be implemented. Thus, the quantities of levels included in the mapping 330-a and the mapping 330-b may depend on the type and configuration of memory cells of an associated memory device.

The mapping 330-a may include a plurality of first bins, which may refer to a logical arrangement (e.g., a logical groping) of a word line group of data that has a same or similar age. For example, the bin 1 may be associated with a first age range (e.g., a first duration that data has been stored to one or more memory cells, a first duration since the most recent program operation of the data), the bin 2 may be associated with a second age range, and so on. In some instances, each subsequent bin may be associated with relatively older data and thus the associated memory cells may be less likely to retain a charge. That is, the bin 7 may be associated with relatively higher magnitudes of reference voltage value adjustments than the bin 1 because the associated memory cells may be less likely to have held an initial charge. Each bin may be associated with a different age range, and the granularity of the mapping 330-a, including a size of a range of each bin as well as quantity of bins stored to the mapping 330-a may be a matter of design (e.g., may be determined at manufacture, may be selected by a user based on a product data sheet, or the like).

The controller may utilize one or more timers, time stamps, or the like, to determine a time since program for one or more memory cells and may map the time to a respective bin in the mapping 330-a. After the controller determines which bin from the mapping 330-a the data of a word line group is associated with (e.g., how long it has been since the word line group was programmed), the controller may select first read voltage shifts for the reference voltage values (e.g., the levels) for the respective word line group. As an example, the controller may determine (e.g., using a timer, based on a timestamp of when the data was written or a program time of the data) that data for a first word line group is associated with bin 1. As such, the controller may select the first read voltage shifts for the reference voltage values for levels 1 through 7 as 0 mV, −10 mV, −20 mV, −20 mV, −30 mV, −40 mV, and −60 mV, respectively. As described herein, these reference voltage value adjustment values are merely exemplary, and the controller may adjust the read voltage shift values for levels 1 through 7 by any value based on a corresponding mapping 330-a used by the controller.

The mapping 330-b may include a plurality of second bins, which may each represent or otherwise correspond to a respective delta temperature (e.g., ΔT) between a TSU (e.g., a first temperature at a time the data was programmed) and a TRO (e.g., a second temperature at a time the data is read or refreshed). For example, the bin 1 may be associated with a first delta temperature (e.g., −120 degrees Celsius), the bin 2 may be associated with a second delta temperature (e.g., −80 degrees Celsius), and so on. Each bin may be associated with a different delta temperature range, and the granularity of the mapping 330-b, including a size of a range of each bin as well as quantity of bins stored to the mapping 330-b may be a matter of design (e.g., may be determined at manufacture, may be selected by a user based on a product data sheet, or the like). In some other examples, the plurality of second bins in the mapping 330-b may refer to categories (e.g., classifications, types) of cross-temperature conditions. For example, the mapping 330-b may have a different quantity of bins than shown (e.g., four bins), and the bin 1 may be associated with a HL cross-temperature condition, the bin 2 may be associated with a LL cross-temperature condition, the bin 3 may be associated with a HH cross-temperature condition, and the bin 4 may be associated with a LH cross-temperature condition. In some examples, the bins may be defined according to a combination of delta temperature values and cross-temperature categories.

The mapping 330-b may not include offset information for the first level, in some examples, if the first level (e.g., Lv 7) is used as a reference for determining the cross temperature. That is, because the first level is a reference level, no additional offset to account for a change in temperature may be applied, and the offsets for the other levels may be calculated or programmed (e.g., configured) to the mapping 330-b accordingly (e.g., with reference to the first level).

The controller may use one or more temperature sensors or other components to determine a change in temperature over time and may then map that change to a bin in the mapping 330-b. After the controller determines which bin from the mapping 330-b the data of a word line group is associated with, the controller may select second read voltage shifts for the reference voltage values (e.g., the levels) for the respective word line group. As an example, the controller may determine that data for a first word line group has a cross-temperature difference of −120 degrees Celsius and is associated with bin 1. As such, the controller may select the second read voltage shifts for the reference voltage values for levels 1 through 7 as 90 mV, 90 mV, 90 mV, 90 mV, 90 mV, 90 mV, and 0 mV, respectively. As described herein, these reference voltage value adjustment values are merely exemplary, and the controller may adjust the read voltage shift values for levels 1 through 7 by any value, including values that differ per level.

After selecting the first read voltage shifts and the second read voltage shifts, the controller (or another component of the memory device) may combine the first read voltage shifts and the second read voltage shifts to determine total read voltage shift values. For example, the controller may sum the first read voltage shifts and the second read voltage shifts to determine the total read voltage shift values. Additionally, or alternatively, the controller may apply some weighted average or other function to calculate a total read voltage shift value based on the two read voltage shifts. The memory system may refresh memory cells for each word line group and for each level according to the total read voltage shift values (e.g., according to the sum of a corresponding first read voltage shift value from the mapping 330-a and a corresponding second read voltage shift value from the mapping 330-b). For example, the memory system may refresh and re-calibrate the memory cells such that a read voltage for accessing a given logic state is offset by the read voltage offset indicated from the mappings 330-a and 330-b.

The mapping 330-a, the mapping 330-b, or both may be stored at the memory system. In some examples, the memory system may store the mapping 330-a in a first table format within volatile memory (e.g., DRAM) of the memory system and may store the mapping 330-b in a second table format within volatile memory of the memory system. The memory cells (e.g., word line groups) for performing read voltage calibration may be included in non-volatile memory (e.g., NAND memory) of the memory system. In some examples, the mapping 330-a, the mapping 330-b, or both, may be generated by the memory system based on one or more testing operations or procedures performed by the memory system. For example, the mapping 330-a, the mapping 330-b, or both, may be determined based on test data.

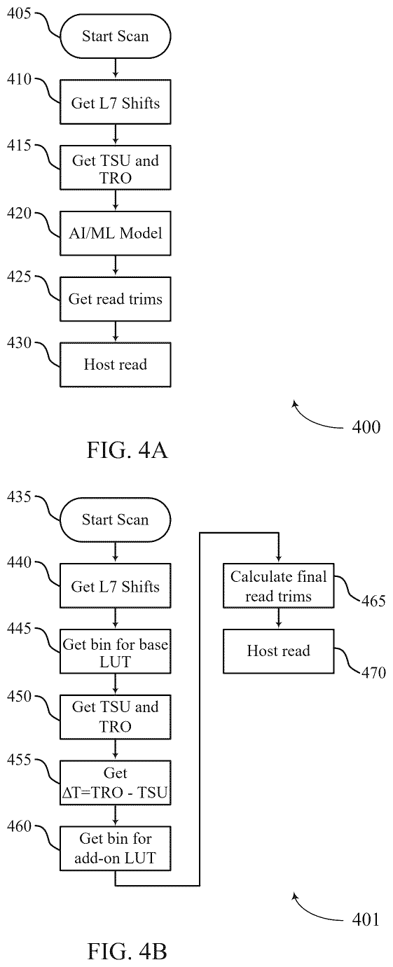

FIG. 4A shows an example of a flowchart 400 that supports cross temperature read voltage calibration for a memory system in accordance with examples as disclosed herein. Operations of the flowchart 400 may be implemented by a memory system 110 (e.g., a memory system controller 115, one or more local controllers 135, or a combination thereof). The flowchart 400 is depicted to start at 405 and end at 430, but may include additional operations (not shown), or operations may be omitted, modified, or performed in a different order in accordance with the described techniques.

At 405, the memory system may initiate a read voltage calibration process. For example, the memory system may start a scan through memory cells (e.g., according to word line groups or some other granularity) of the memory system. As part of the read voltage calibration process, the memory system may determine to refresh one or more memory cells. For example, the memory system may identify one or more memory cells (e.g., of a word line group) for which to perform read voltage calibration. Prior to 405, the memory system may have written data to the memory cells at a first time and at a first temperature (e.g., a TSU). The memory system may store (e.g., in volatile memory or elsewhere in the memory system), information that indicates the first time and the first temperature based on the programming.

At 410, the memory system may determine, based on initiating the read voltage calibration for the identified memory cells at a second time that is after the first time, a shift in a read voltage associated with a first logic state (e.g., first level shifts, level 7 shifts) of multiple logic states (e.g., multiple levels, levels 0-7) of the memory cells between the first time and the second time. The first logic state may be a highest logic state of the multiple logic states of the memory cells, in some examples, or some other logic state.

At 415, the memory system may measure (e.g., based on initiating the read voltage calibration) a second temperature (e.g., a TRO) associated with the memory cells at a third time that is at the same time as or after the second time. As such, the memory system may determine (e.g., have access to) both the TSU and the TRO of the memory cells. The memory system may measure the second temperature and determine the shift in read voltage in parallel or in any order.

At 420, the memory system may input, to a linear regression model or an AI model, the shift in the read voltage associated with the first logic state and a difference (e.g., ΔT) between the first temperature and the second temperature. The memory system may input the shift and the temperature change for a given memory cell, a given word line group, or some other granularity.

At 425, the memory system may receive, as output from the linear regression model or the AI model, one or more read voltage offset values for the multiple logic states of the memory cells. The read voltage offset values may be based on a relationship between read voltage shifts of the first logic state of a memory cell, a time since a write, and a change in temperature across the multiple logic states. The read voltage offset values may be applied to each memory cell in a corresponding word line group. Additionally, or alternatively, the model may output read voltage offset values (e.g., trims) for multiple word line groups.

At 430, the memory system may apply the read voltage offset values to the memory cells. For example, the memory system may apply the read voltage offset values to the memory cells as part of a refresh operation to refresh the multiple logic states of the memory cells. The memory system may access, based on an access operation, the memory cells in accordance with read voltages associated with the multiple logic states. The read voltages used during the access operation may correspond to default or calibrated read voltages configured for the memory system (e.g., based on a standard or average charge of the memory cells). The application of the read voltage offset values may align the memory cell charges and corresponding threshold voltages with the default or calibrated read voltages to improve reliability and accuracy. The memory system may perform the access of the memory cells in response to a command (e.g., a read command) from a host system (e.g., a host system 105).

FIG. 4B shows an example of a flowchart 401 that supports cross temperature read voltage calibration for a memory system in accordance with examples as disclosed herein. Operations of the flowchart 401 may be implemented by a memory system 110 (e.g., a memory system controller 115, one or more local controllers 135, or a combination thereof). The flowchart 401 is depicted to start at 435 and end at 470, but may include additional operations (not shown), or operations may be omitted, modified, or performed in a different order in accordance with the described techniques.

At 435, the memory system may initiate a read voltage calibration process. For example, the memory system may start a scan through memory cells (e.g., word line groups) of the memory system. As part of the read voltage calibration process, the memory system may determine to refresh one or more memory cells. For example, the memory system may identify one or more memory cells (e.g., of a word line group) for which to perform read voltage calibration. Prior to 405, the memory system may have written data to the memory cells at a first time and at a first temperature (e.g., a TSU). The memory system may store (e.g., in volatile memory or elsewhere in the memory system), information that indicates the first time and the first temperature based on the programming.

At 440, the memory system may determine, based on initiating the read voltage calibration for the identified memory cells at a second time that is after the first time, a shift in a read voltage associated with a first logic state (e.g., first level shifts, level 7 shifts) of multiple logic states (e.g., multiple levels, levels 0-7) of the memory cells between the first time and the second time. The first logic state may be a highest logic state of the multiple logic states of the memory cells, in some examples, or some other logic state.

At 445, the memory system may scan first mapping information (e.g., a base LUT) stored by the memory system. The first mapping information may indicate a respective first relationship, for each logic state of the multiple logic states, between a duration since a most recent program operation for the respective logic state and a corresponding first shift in a read voltage for the respective logic state. The first mapping information may represent an example of the mapping 330-a described with reference to FIG. 3B.

At 450, the memory system may measure (e.g., based on initiating the read voltage calibration) a second temperature (e.g., a TRO) associated with the memory cells at a third time that is at the same time as or after the second time. As such, the memory system may determine (e.g., have access to) both the TSU and the TRO of the memory cells. At 455, the memory system may determine a difference between the first temperature (e.g., TSU) of the memory cells at the first time and the second temperature (e.g., TRO) of the memory cells at the second time.

At 460, the memory system may scan second mapping information (e.g., an add-on LUT) stored by the memory system. The second mapping information may indicate a respective second relationship, for each logic state of the multiple logic states, between a change in temperature since the most recent program operation (e.g., a difference between TSU and TRO) for the respective logic state and a corresponding second shift in the read voltage for the respective logic state. The second mapping information may represent an example of the mapping 330-b described with referenced to FIG. 3B. The memory system may measure the second temperature, determine the shift in read voltage, and scan corresponding mapping information in parallel or in any order in time.

At 465, the memory system may combine, for each logic state of the multiple logic states, the corresponding first shift in the read voltage (e.g., from the first mapping information) and the corresponding second shift in the read voltage (e.g., from the second mapping information) to obtain a respective read voltage offset value (e.g., a total read voltage shift value). The read voltage offset values may include read voltage offset values for each logic state of the multiple logic states. The read voltage offset values may be applied to each memory cell in a corresponding word line group. Additionally, or alternatively, the memory system may calculate read voltage offset values (e.g., trims) for multiple word line groups (e.g., using multiple sets or pairs of LUTs).

At 470, the memory system may apply the read voltage offset values to the memory cells. For example, the memory system may apply the read voltage offset values to the memory cells as part of a refresh operation to refresh the multiple logic states of the memory cells. The memory system may access, based on an access operation, the memory cells in accordance with read voltages associated with the multiple logic states. The read voltages used during the access operation may correspond to default or calibrated read voltages configured for the memory system (e.g., based on a standard or average charge of the memory cells). The application of the read voltage offset values may align the memory cell charges and corresponding threshold voltages with the default or calibrated read voltages to improve reliability and accuracy. The memory system may perform the access of the memory cells in response to a command (e.g., a read command) from a host system (e.g., a host system 105).

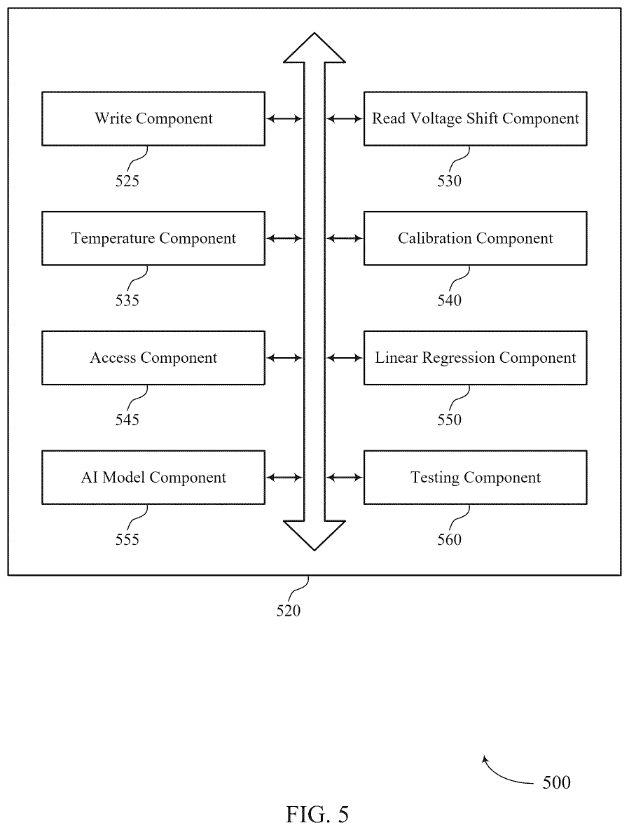

FIG. 5 shows a block diagram 500 of a memory system 520 that supports cross temperature read voltage calibration for a memory system in accordance with examples as disclosed herein. The memory system 520 may be an example of aspects of a memory system as described with reference to FIGS. 1 through 4. The memory system 520, or various components thereof, may be an example of means for performing various aspects of cross temperature read voltage calibration for a memory system as described herein. For example, the memory system 520 may include a write component 525, a read voltage shift component 530, a temperature component 535, a calibration component 540, an access component 545, a linear regression component 550, an AI model component 555, a testing component 560, or any combination thereof. Each of these components, or components of subcomponents thereof (e.g., one or more processors, one or more memories), may communicate, directly or indirectly, with one another (e.g., via one or more buses).

The write component 525 may be configured as or otherwise support a means for writing, at a first time, data to one or more memory cells of the memory system, the one or more memory cells associated with a first temperature at the first time. The read voltage shift component 530 may be configured as or otherwise support a means for determining, based at least in part on a read voltage calibration for the one or more memory cells at a second time that is after the first time, a shift in a read voltage associated with a first logic state of a plurality of logic states of the one or more memory cells between the first time at which the data was written to the one or more memory cells and the second time. The temperature component 535 may be configured as or otherwise support a means for measuring, based at least in part on the read voltage calibration for the one or more memory cells, a second temperature associated with the one or more memory cells at a third time that is at the same as or after the second time. The calibration component 540 may be configured as or otherwise support a means for generating, based at least in part on the shift in the read voltage associated with the first logic state and on a difference between the first temperature of the one or more memory cells at the first time and the second temperature of the one or more memory cells at the third time, one or more read voltage offset values associated with calibration of the plurality of logic states of the one or more memory cells.

In some examples, the calibration component 540 may be configured as or otherwise support a means for applying, based at least in part on a refresh operation after the read voltage calibration, the one or more read voltage offset values to the one or more memory cells where application of the one or more read voltage offset values refreshes the plurality of logic states of the one or more memory cells. In some examples, the access component 545 may be configured as or otherwise support a means for accessing, based at least in part on an access operation, the one or more memory cells in accordance with a plurality of read voltages associated with the plurality of logic states, where the plurality of read voltages is based at least in part on applying the one or more read voltage offset values.

In some examples, the linear regression component 550 may be configured as or otherwise support a means for generating, based at least in part on one or more training operations, a linear regression model that estimates a relationship between read voltage shifts of the first logic state of a memory cell, a time since a write, and a change in temperature across the plurality of logic states. In some examples, the linear regression component 550 may be configured as or otherwise support a means for generating the one or more read voltage offset values by calculating, in accordance with the linear regression model, the shift in the read voltage associated with the first logic state, and the difference between the first temperature and the second temperature, the one or more read voltage offset values for the plurality of logic states of the one or more memory cells.

In some examples, the AI model component 555 may be configured as or otherwise support a means for generating, based at least in part on one or more training operations, an artificial intelligence model configured to estimate a relationship between read voltage shifts of the first logic state of a memory cell, a time since a write, and a change in temperature across the plurality of logic states. In some examples, the AI model component 555 may be configured as or otherwise support a means for generating the one or more read voltage offset values by inputting, to the artificial intelligence model, the shift in the read voltage associated with the first logic state and the difference between the first temperature and the second temperature, where an output of the artificial intelligence model includes the one or more read voltage offset values for the plurality of logic states of the one or more memory cells based at least in part on the relationship.

In some examples, the calibration component 540 may be configured as or otherwise support a means for scanning first mapping information stored by the memory system, where the first mapping information indicates a respective first relationship, for each logic state of the plurality of logic states, between a duration since a most recent program operation for the respective logic state and a corresponding first shift in a read voltage for the respective logic state. In some examples, the calibration component 540 may be configured as or otherwise support a means for scanning second mapping information stored by the memory system, where the second mapping information indicates a respective second relationship, for each logic state of the plurality of logic states, between a change in temperature since the most recent program operation for the respective logic state and a corresponding second shift in the read voltage for the respective logic state. In some examples, the calibration component 540 may be configured as or otherwise support a means for combining, for each logic state of the plurality of logic states, the corresponding first shift in the read voltage and the corresponding second shift in the read voltage to obtain a respective read voltage offset value, where the one or more read voltage offset values include read voltage offset values for each logic state of the plurality of logic states.

In some examples, the first mapping information and the second mapping information are further associated with each word line group of a plurality of word line groups within the memory system, the one or more read voltage offset values including read voltage offset values for each unique pair of a logic state of the plurality of logic states and a word line group of the plurality of word line groups.

In some examples, the testing component 560 may be configured as or otherwise support a means for performing one or more testing operations. In some examples, the calibration component 540 may be configured as or otherwise support a means for generating the first mapping information and the second mapping information based at least in part on the one or more testing operations. In some examples, the calibration component 540 may be configured as or otherwise support a means for storing the first mapping information and the second mapping information at the memory system, where scanning the first mapping information at the second mapping information is based at least in part on the storing.

In some examples, to support storing the first mapping information and the second mapping information, the calibration component 540 may be configured as or otherwise support a means for storing the first mapping information in a first table format within volatile memory of the memory system. In some examples, to support storing the first mapping information and the second mapping information, the calibration component 540 may be configured as or otherwise support a means for storing the second mapping information in a second table format within the volatile memory, where the one or more memory cells are included in a non-volatile memory of the memory system.

In some examples, the one or more read voltage offset values are associated with the plurality of logic states and a plurality of word line groups of the one or more memory cells. In some examples, each read voltage offset value of the one or more read voltage offset values corresponds to a respective logic state of the plurality of logic states and a respective word line group of the plurality of word line groups.

In some examples, the first logic state is associated with a greatest read voltage threshold of a plurality of read voltage thresholds associated with the plurality of logic states.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

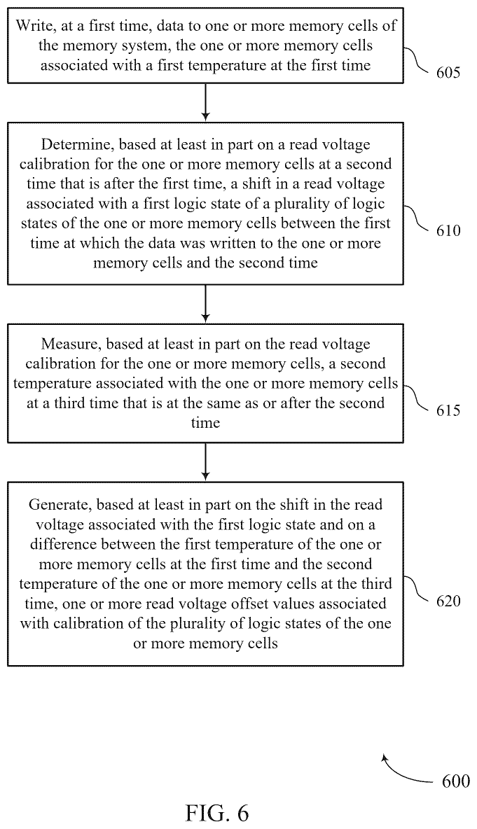

FIG. 6 shows a flowchart illustrating a method 600 that supports cross temperature read voltage calibration for a memory system in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include writing, at a first time, data to one or more memory cells of the memory system, the one or more memory cells associated with a first temperature at the first time. In some examples, aspects of the operations of 605 may be performed by a write component 525 as described with reference to FIG. 5.

At 610, the method may include determining, based at least in part on a read voltage calibration for the one or more memory cells at a second time that is after the first time, a shift in a read voltage associated with a first logic state of a plurality of logic states of the one or more memory cells between the first time at which the data was written to the one or more memory cells and the second time. In some examples, aspects of the operations of 610 may be performed by a read voltage shift component 530 as described with reference to FIG. 5.

At 615, the method may include measuring, based at least in part on the read voltage calibration for the one or more memory cells, a second temperature associated with the one or more memory cells at a third time that is at the same as or after the second time. In some examples, aspects of the operations of 615 may be performed by a temperature component 535 as described with reference to FIG. 5.

At 620, the method may include generating, based at least in part on the shift in the read voltage associated with the first logic state and on a difference between the first temperature of the one or more memory cells at the first time and the second temperature of the one or more memory cells at the third time, one or more read voltage offset values associated with calibration of the plurality of logic states of the one or more memory cells. In some examples, aspects of the operations of 620 may be performed by a calibration component 540 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for writing, at a first time, data to one or more memory cells of the memory system, the one or more memory cells associated with a first temperature at the first time; determining, based at least in part on a read voltage calibration for the one or more memory cells at a second time that is after the first time, a shift in a read voltage associated with a first logic state of a plurality of logic states of the one or more memory cells between the first time at which the data was written to the one or more memory cells and the second time; measuring, based at least in part on the read voltage calibration for the one or more memory cells, a second temperature associated with the one or more memory cells at a third time that is at the same as or after the second time; and generating, based at least in part on the shift in the read voltage associated with the first logic state and on a difference between the first temperature of the one or more memory cells at the first time and the second temperature of the one or more memory cells at the third time, one or more read voltage offset values associated with calibration of the plurality of logic states of the one or more memory cells.

Aspect 2: The method, apparatus, or non-transitory computer-readable medium of aspect 1, further including operations, features, circuitry, logic, means, or instructions, or any combination thereof for applying, based at least in part on a refresh operation after the read voltage calibration, the one or more read voltage offset values to the one or more memory cells where application of the one or more read voltage offset values refreshes the plurality of logic states of the one or more memory cells and accessing, based at least in part on an access operation, the one or more memory cells in accordance with a plurality of read voltages associated with the plurality of logic states, where the plurality of read voltages is based at least in part on applying the one or more read voltage offset values.

Aspect 3: The method, apparatus, or non-transitory computer-readable medium of any of aspects 1 through 2, further including operations, features, circuitry, logic, means, or instructions, or any combination thereof for generating, based at least in part on one or more training operations, a linear regression model that estimates a relationship between read voltage shifts of the first logic state of a memory cell, a time since a write, and a change in temperature across the plurality of logic states, where generating the one or more read voltage offset values includes and calculating, in accordance with the linear regression model, the shift in the read voltage associated with the first logic state, and the difference between the first temperature and the second temperature, the one or more read voltage offset values for the plurality of logic states of the one or more memory cells.

Aspect 4: The method, apparatus, or non-transitory computer-readable medium of any of aspects 1 through 3, further including operations, features, circuitry, logic, means, or instructions, or any combination thereof for generating, based at least in part on one or more training operations, an artificial intelligence model configured to estimate a relationship between read voltage shifts of the first logic state of a memory cell, a time since a write, and a change in temperature across the plurality of logic states, where generating the one or more read voltage offset values includes and inputting, to the artificial intelligence model, the shift in the read voltage associated with the first logic state and the difference between the first temperature and the second temperature, where an output of the artificial intelligence model includes the one or more read voltage offset values for the plurality of logic states of the one or more memory cells based at least in part on the relationship.

Aspect 5: The method, apparatus, or non-transitory computer-readable medium of any of aspects 1 through 4, further including operations, features, circuitry, logic, means, or instructions, or any combination thereof for scanning first mapping information stored by the memory system, where the first mapping information indicates a respective first relationship, for each logic state of the plurality of logic states, between a duration since a most recent program operation for the respective logic state and a corresponding first shift in a read voltage for the respective logic state; scanning second mapping information stored by the memory system, where the second mapping information indicates a respective second relationship, for each logic state of the plurality of logic states, between a change in temperature since the most recent program operation for the respective logic state and a corresponding second shift in the read voltage for the respective logic state; and combining, for each logic state of the plurality of logic states, the corresponding first shift in the read voltage and the corresponding second shift in the read voltage to obtain a respective read voltage offset value, where the one or more read voltage offset values include read voltage offset values for each logic state of the plurality of logic states.

Aspect 6: The method, apparatus, or non-transitory computer-readable medium of aspect 5, where the first mapping information and the second mapping information are further associated with each word line group of a plurality of word line groups within the memory system, the one or more read voltage offset values including read voltage offset values for each unique pair of a logic state of the plurality of logic states and a word line group of the plurality of word line groups.

Aspect 7: The method, apparatus, or non-transitory computer-readable medium of any of aspects 5 through 6, further including operations, features, circuitry, logic, means, or instructions, or any combination thereof for performing one or more testing operations; generating the first mapping information and the second mapping information based at least in part on the one or more testing operations; and storing the first mapping information and the second mapping information at the memory system, where scanning the first mapping information at the second mapping information is based at least in part on the storing.

Aspect 8: The method, apparatus, or non-transitory computer-readable medium of aspect 7, where storing the first mapping information and the second mapping information includes operations, features, circuitry, logic, means, or instructions, or any combination thereof for storing the first mapping information in a first table format within volatile memory of the memory system and storing the second mapping information in a second table format within the volatile memory, where the one or more memory cells are included in a non-volatile memory of the memory system.

Aspect 9: The method, apparatus, or non-transitory computer-readable medium of any of aspects 1 through 8, where the one or more read voltage offset values are associated with the plurality of logic states and a plurality of word line groups of the one or more memory cells and each read voltage offset value of the one or more read voltage offset values corresponds to a respective logic state of the plurality of logic states and a respective word line group of the plurality of word line groups.

Aspect 10: The method, apparatus, or non-transitory computer-readable medium of any of aspects 1 through 9, where the first logic state is associated with a greatest read voltage threshold of a plurality of read voltage thresholds associated with the plurality of logic states.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
write, at a first time, data to one or more memory cells of the memory system, the one or more memory cells associated with a first temperature at the first time;
determine, based at least in part on a read voltage calibration for the one or more memory cells at a second time that is after the first time, a shift in a read voltage associated with a first logic state of a plurality of logic states of the one or more memory cells between the first time at which the data was written to the one or more memory cells and the second time;
measure, based at least in part on the read voltage calibration for the one or more memory cells, a second temperature associated with the one or more memory cells at a third time that is at the same as or after the second time; and
generate, based at least in part on the shift in the read voltage associated with the first logic state and on a difference between the first temperature of the one or more memory cells at the first time and the second temperature of the one or more memory cells at the third time, one or more read voltage offset values associated with calibration of the plurality of logic states of the one or more memory cells.

2. The memory system of claim 1, wherein the processing circuitry is further configured to cause the memory system to:
apply, based at least in part on a refresh operation after the read voltage calibration, the one or more read voltage offset values to the one or more memory cells wherein application of the one or more read voltage offset values refreshes the plurality of logic states of the one or more memory cells; and
access, based at least in part on an access operation, the one or more memory cells in accordance with a plurality of read voltages associated with the plurality of logic states, wherein the plurality of read voltages is based at least in part on applying the one or more read voltage offset values.

3. The memory system of claim 1, wherein the processing circuitry is further configured to cause the memory system to:
generate, based at least in part on one or more training operations, a linear regression model that estimates a relationship between read voltage shifts of the first logic state of a memory cell, a time since a write, and a change in temperature across the plurality of logic states, wherein generating the one or more read voltage offset values comprises:
calculate, in accordance with the linear regression model, the shift in the read voltage associated with the first logic state, and the difference between the first temperature and the second temperature, the one or more read voltage offset values for the plurality of logic states of the one or more memory cells.

4. The memory system of claim 1, wherein the processing circuitry is further configured to cause the memory system to:
generate, based at least in part on one or more training operations, an artificial intelligence model configured to estimate a relationship between read voltage shifts of the first logic state of a memory cell, a time since a write, and a change in temperature across the plurality of logic states, wherein generating the one or more read voltage offset values comprises:
input, to the artificial intelligence model, the shift in the read voltage associated with the first logic state and the difference between the first temperature and the second temperature, wherein an output of the artificial intelligence model comprises the one or more read voltage offset values for the plurality of logic states of the one or more memory cells based at least in part on the relationship.

5. The memory system of claim 1, wherein the processing circuitry is further configured to cause the memory system to:
scan first mapping information stored by the memory system, wherein the first mapping information indicates a respective first relationship, for each logic state of the plurality of logic states, between a duration since a most recent program operation for the respective logic state and a corresponding first shift in a read voltage for the respective logic state;
scan second mapping information stored by the memory system, wherein the second mapping information indicates a respective second relationship, for each logic state of the plurality of logic states, between a change in temperature since the most recent program operation for the respective logic state and a corresponding second shift in the read voltage for the respective logic state; and
combine, for each logic state of the plurality of logic states, the corresponding first shift in the read voltage and the corresponding second shift in the read voltage to obtain a respective read voltage offset value, wherein the one or more read voltage offset values comprise read voltage offset values for each logic state of the plurality of logic states.

6. The memory system of claim 5, wherein the first mapping information and the second mapping information are further associated with each word line group of a plurality of word line groups within the memory system, the one or more read voltage offset values comprising read voltage offset values for each unique pair of a logic state of the plurality of logic states and a word line group of the plurality of word line groups.

7. The memory system of claim 5, wherein the processing circuitry is further configured to cause the memory system to:
perform one or more testing operations;
generate the first mapping information and the second mapping information based at least in part on the one or more testing operations; and
store the first mapping information and the second mapping information at the memory system, wherein scanning the first mapping information at the second mapping information is based at least in part on the storing.

8. The memory system of claim 7, wherein storing the first mapping information and the second mapping information comprises the processing circuitry configured to cause the memory system to:
store the first mapping information in a first table format within volatile memory of the memory system; and
store the second mapping information in a second table format within the volatile memory, wherein the one or more memory cells are included in a non-volatile memory of the memory system.

9. The memory system of claim 1, wherein:
the one or more read voltage offset values are associated with the plurality of logic states and a plurality of word line groups of the one or more memory cells; and
each read voltage offset value of the one or more read voltage offset values corresponds to a respective logic state of the plurality of logic states and a respective word line group of the plurality of word line groups.

10. The memory system of claim 1, wherein the first logic state is associated with a greatest read voltage threshold of a plurality of read voltage thresholds associated with the plurality of logic states.

11. A method by a memory system, comprising:
writing, at a first time, data to one or more memory cells of the memory system, the one or more memory cells associated with a first temperature at the first time;
determining, based at least in part on a read voltage calibration for the one or more memory cells at a second time that is after the first time, a shift in a read voltage associated with a first logic state of a plurality of logic states of the one or more memory cells between the first time at which the data was written to the one or more memory cells and the second time;
measuring, based at least in part on the read voltage calibration for the one or more memory cells, a second temperature associated with the one or more memory cells at a third time that is at the same as or after the second time; and
generating, based at least in part on the shift in the read voltage associated with the first logic state and on a difference between the first temperature of the one or more memory cells at the first time and the second temperature of the one or more memory cells at the third time, one or more read voltage offset values associated with calibration of the plurality of logic states of the one or more memory cells.

12. The method of claim 11, further comprising:
applying, based at least in part on a refresh operation after the read voltage calibration, the one or more read voltage offset values to the one or more memory cells wherein application of the one or more read voltage offset values refreshes the plurality of logic states of the one or more memory cells; and
accessing, based at least in part on an access operation, the one or more memory cells in accordance with a plurality of read voltages associated with the plurality of logic states, wherein the plurality of read voltages is based at least in part on applying the one or more read voltage offset values.

13. The method of claim 11, further comprising:
generating, based at least in part on one or more training operations, a linear regression model that estimates a relationship between read voltage shifts of the first logic state of a memory cell, a time since a write, and a change in temperature across the plurality of logic states, wherein generating the one or more read voltage offset values comprises:
calculating, in accordance with the linear regression model, the shift in the read voltage associated with the first logic state, and the difference between the first temperature and the second temperature, the one or more read voltage offset values for the plurality of logic states of the one or more memory cells.

14. The method of claim 11, further comprising:
generating, based at least in part on one or more training operations, an artificial intelligence model configured to estimate a relationship between read voltage shifts of the first logic state of a memory cell, a time since a write, and a change in temperature across the plurality of logic states, wherein generating the one or more read voltage offset values comprises:
inputting, to the artificial intelligence model, the shift in the read voltage associated with the first logic state and the difference between the first temperature and the second temperature, wherein an output of the artificial intelligence model comprises the one or more read voltage offset values for the plurality of logic states of the one or more memory cells based at least in part on the relationship.

15. The method of claim 11, further comprising:
scanning first mapping information stored by the memory system, wherein the first mapping information indicates a respective first relationship, for each logic state of the plurality of logic states, between a duration since a most recent program operation for the respective logic state and a corresponding first shift in a read voltage for the respective logic state;
scanning second mapping information stored by the memory system, wherein the second mapping information indicates a respective second relationship, for each logic state of the plurality of logic states, between a change in temperature since the most recent program operation for the respective logic state and a corresponding second shift in the read voltage for the respective logic state; and
combining, for each logic state of the plurality of logic states, the corresponding first shift in the read voltage and the corresponding second shift in the read voltage to obtain a respective read voltage offset value, wherein the one or more read voltage offset values comprise read voltage offset values for each logic state of the plurality of logic states.

16. The method of claim 15, wherein the first mapping information and the second mapping information are further associated with each word line group of a plurality of word line groups within the memory system, the one or more read voltage offset values comprising read voltage offset values for each unique pair of a logic state of the plurality of logic states and a word line group of the plurality of word line groups.

17. The method of claim 15, further comprising:
performing one or more testing operations;
generating the first mapping information and the second mapping information based at least in part on the one or more testing operations; and
storing the first mapping information and the second mapping information at the memory system, wherein scanning the first mapping information at the second mapping information is based at least in part on the storing.

18. The method of claim 17, wherein storing the first mapping information and the second mapping information comprises:
storing the first mapping information in a first table format within volatile memory of the memory system; and
storing the second mapping information in a second table format within the volatile memory, wherein the one or more memory cells are included in a non-volatile memory of the memory system.

19. The method of claim 11, wherein:
the one or more read voltage offset values are associated with the plurality of logic states and a plurality of word line groups of the one or more memory cells; and
each read voltage offset value of the one or more read voltage offset values corresponds to a respective logic state of the plurality of logic states and a respective word line group of the plurality of word line groups.

20. The method of claim 11, wherein the first logic state is associated with a greatest read voltage threshold of a plurality of read voltage thresholds associated with the plurality of logic states.

21. A non-transitory computer-readable medium storing code, the code comprising instructions executable by one or more processors to:
write, at a first time, data to one or more memory cells of a memory system, the one or more memory cells associated with a first temperature at the first time;
determine, based at least in part on a read voltage calibration for the one or more memory cells at a second time that is after the first time, a shift in a read voltage associated with a first logic state of a plurality of logic states of the one or more memory cells between the first time at which the data was written to the one or more memory cells and the second time;
measure, based at least in part on the read voltage calibration for the one or more memory cells, a second temperature associated with the one or more memory cells at a third time that is at the same as or after the second time; and
generate, based at least in part on the shift in the read voltage associated with the first logic state and on a difference between the first temperature of the one or more memory cells at the first time and the second temperature of the one or more memory cells at the third time, one or more read voltage offset values associated with calibration of the plurality of logic states of the one or more memory cells.

22. The non-transitory computer-readable medium of claim 21, wherein the instructions are further executable by the one or more processors to:
apply, based at least in part on a refresh operation after the read voltage calibration, the one or more read voltage offset values to the one or more memory cells wherein application of the one or more read voltage offset values refreshes the plurality of logic states of the one or more memory cells; and
access, based at least in part on an access operation, the one or more memory cells in accordance with a plurality of read voltages associated with the plurality of logic states, wherein the plurality of read voltages is based at least in part on applying the one or more read voltage offset values.
